(19) United States
(12) Patent Application Publication
(10) Pub. No.: US 2026/0314044 A1
(43) Pub. Date: Oct. 8, 2026

(54) TOP SOURCE DRAIN AND ASSOCATED ILD FORMATION WITHIN A STACKED TRANSISTOR

(71) Applicant: International Business Machines Corporation, Armonk, NY (US)

(72) Inventors: Eunsoo Cho, Albany, NY (US); Ruilong Xie, Niskayuna, NY (US); Thanh Nguyen, Troy, NY (US); Shay Reboh, Guilderland, NY (US); Kamal Rudra, Albany, NY (US); Shravana Kumar Katakam, Lehi, UT (US); Ashim Dutta, Clifton Park, NY (US)

(21) Appl. No.: 19/098,202

(22) Filed: Apr. 2, 2025

(51) Int. Cl. H10D 84/83; H10D 84/01

(52) U.S. Cl. CPC H10D 84/832; H10D 84/0149; H10D 84/8312

(57) ABSTRACT

A stacked transistor is presented. The stacked transistor includes a top source/drain (S/D) region that has a lower portion and an upper portion. The stacked transistor includes a bottom interlayer dielectric (ILD) in contact with the lower portion of the top S/D region. The stacked transistor includes a top ILD in contact with the upper portion of the top S/D region.

### BACKGROUND

Conventional transistors, such as semiconductor IC devices, or the like, incorporate planar field effect transistors (FETs) in which current flows through a semiconducting channel between a source and a drain in response to a voltage applied to a control gate. The semiconductor industry strives to obey Moore's law, which holds that each successive generation of integrated circuit devices shrinks to half its size and operates twice as fast. As device dimensions have shrunk, however, conventional silicon device geometries and materials have had trouble maintaining switching speeds without incurring failures such as, for example, leaking current from the device into the semiconductor substrate. Several new technologies emerged that allowed chip designers to continue shrinking transistor sizes. A FET, generally, is a transistor in which output current, i.e., source-drain current, is controlled by a voltage applied to an associated gate. A FET typically has three terminals, i.e., a gate structure, a source region, and a drain region. A gate structure is a structure used to control output current (i.e., flow of carriers in the channel) of a semiconducting device through electrical or magnetic fields. A channel is the region of the FET underlying the gate structure and between the source and drain of the semiconductor IC device that becomes conductive when the semiconductor device is turned on. The source is a doped region in the semiconductor IC device, in which a majority carriers are flowing into the channel. A drain is a doped region in the semiconductor IC device located at the end of the channel, in which carriers are flowing out of the transistor through the drain.

One technology change modified the structure of the FET from a planar device to a three-dimensional device in which the semiconducting channel was replaced by a fin that extends out from the plane of the substrate. In such a device, commonly referred to as a FinFET, the control gate wraps around three sides of the fin to influence current flow from three surfaces instead of one. The improved control achieved with a 3D design results in faster switching performance and reduced current leakage. Building taller devices has also permitted increasing the device density within the same footprint that had previously been occupied by a planar FET.

The FinFET concept was further extended by developing a gate all-around FET, or GAA FET, in which the gate fully wraps around one or more channels for maximum control of the current flow therein. In the GAA FET, the channels can take the form of nanolayers, nanosheets, or the like, that are isolated from the substrate. In the GAA FET, channel surfaces are in respective contact with the source and drain and other respective channel surfaces are in contact with and surrounded by the gate.

### SUMMARY

In an embodiment of the present disclosure, a stacked transistor is presented. The stacked transistor includes a top source/drain (S/D) region with a lower portion and an upper portion. The stacked transistor further includes a bottom S/D region below the top S/D region. The stacked transistor further includes a bottom interlayer dielectric (ILD) in contact with the bottom S/D region and in contact with the lower portion of the top S/D region. The stacked transistor further includes a top ILD in contact with the upper portion of the top S/D region.

In another embodiment of the present disclosure, a stacked transistor is presented. The stacked transistor includes a top source/drain (S/D) region comprising a lower portion and an upper portion. The stacked transistor includes a bottom interlayer dielectric (ILD) in contact with the lower portion of the top S/D region. The stacked transistor includes a top ILD in contact with the upper portion of the top S/D region.

In another embodiment of the present disclosure, a stacked transistor is presented. The stacked transistor includes a bottom source/drain (S/D) region. The stacked transistor further includes a top S/D region that is offset from the bottom S/D region. The top S/D region includes a lower portion that is inset relative to an upper portion. The stacked transistor further includes a inter layer dielectric (ILD). The upper portion of the top S/D region comprises a bottom surface that is substantially coplanar with a top surface of the ILD.

The above summary is not intended to describe each illustrated embodiment or every implementation or example of the present disclosure.

### BRIEF DESCRIPTION OF THE DRAWINGS

The drawings included in the disclosure are incorporated into, and form part of, the specification. They illustrate embodiments of the present disclosure and, along with the description, explain the principles of the disclosure. The drawings are illustrative of certain embodiments and do not limit the disclosure.

FIG. 1 depicts a semiconductor IC device that includes a stacked transistor, according to one or more embodiments of the disclosure.

FIG. 2 depicts a partial structure top-down view of an illustrative semiconductor IC device, according to one or more embodiments of the disclosure.

FIG. 3 through FIG. 12 depict various fabrication structure views of an exemplary semiconductor IC device, according to one or more embodiments of the disclosure.

FIG. 13 depicts a flowchart of a method of fabricating a semiconductor IC device, according to one or more embodiments of the disclosure.

### DETAILED DESCRIPTION

The present disclosure describes an illustrative semiconductor IC device that includes a stacked transistor that includes a top transistor stacked over a bottom transistor. The stacked transistor may be fabricated by a process that may reduce formation of undesired dielectric material build up, sometimes referred to in the art as a neck, after the formation of the bottom source/drain regions. This traditional neck may lead to the utilization of an aggressive etch during the fabrication of frontside source/drain contacts in order to break through the neck and at least partially expose the associated bottom source/drain regions. This aggressive etch may be difficult to manage and may undesirably cause frontside contact to gate shorting.

There are many different types of transistors, such as but not limited to FinFETs, GAA FETs, fork sheet FETs, and the like. Though illustrative GAA FETs are depicted in the drawings, embodiments of the present disclosure should not be limited thereto and may be applied to other transistors that include a gate having a reduced gate region or eliminated gate region between dual MDI regions.

The flowcharts and cross-sectional diagrams in the drawings illustrate a method of fabricating semiconductor IC device, such as a processor, FPGA, memory module, or the like. In some alternative implementations, the fabrication steps may occur in a different order than that which is noted in the drawings, and certain additional fabrication steps may be implemented between the steps noted in the drawings. Moreover, any of the layered structures depicted in the drawings may contain multiple sublayers.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the depicted structure(s) as oriented. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

The terms “about,” “substantially,” “approximately,” and variations thereof, are intended to include the degree of error associated with measurement of the particular quantity based upon the equipment available at the time of filing the application. For example, substantial coplanarity between various materials can include an appropriate manufacturing tolerance of ±8%, ±5%, ±2%, or the like, difference between the coplanar materials.

As used herein, the term “coplanar” refers to two surfaces that lie in a common plane. In other words, two surfaces are coplanar if there exists a geometric plane that contains all of the points of both of the surfaces. Accordingly, two surfaces may be referred to as substantially coplanar despite deviations from coplanarity on an atomic scale, so long as those deviations do not impact the desired result of the coplanarity.

As used herein, the terms “selective” or “selectively” in reference to a material removal or etch process denote that the rate of material removal for a first material is greater than the rate of removal for at least another material of the structure to which the material removal process is applied. For example, in certain embodiments, a selective etch may include an etch chemistry that removes a first material selectively to a second material by a ratio of 2:1 or greater, e.g., 5:1, 10:1 or 20:1.

For the sake of brevity, conventional techniques related to semiconductor device and IC fabrication may or may not be described in detail herein. Moreover, the various tasks and process steps described herein can be incorporated into a more comprehensive procedure or process having additional steps or functionality not described in detail herein. Various steps in the manufacture of semiconductor devices are well known and so, in the interest of brevity, many conventional steps will only be mentioned briefly herein or will be omitted entirely without providing the well-known process details.

In general, the various processes used to form a microchip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Turning now to an overview of technologies that are more specifically relevant to aspects of the present disclosure, a metal-oxide-semiconductor field-effect transistor (MOSFET) may be used for amplifying or switching electronic signals. The MOSFET has a source electrode, a drain electrode, and a metal oxide gate electrode. The metal gate portion of the metal oxide gate electrode is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field effect transistors (nFET) and p-type field effect transistors (pFET) are two types of complementary MOSFETs. The nFET includes n-doped source and drain junctions and uses electrons as the current carriers. The pFET includes p-doped source and drain junctions and uses holes as the current carriers. Complementary metal oxide semiconductor (CMOS) is a technology that uses complementary and symmetrical pairs of p-type and n-type MOSFETs to implement logic functions. As mentioned above, hole mobility on the pFET may have an impact on overall device performance.

The wafer footprint of an FET is related to the electrical conductivity of the channel material. If the channel material has a relatively high conductivity, the FET can be made with a correspondingly smaller wafer footprint. A method of increasing channel conductivity and decreasing FET size is to form the channel as a nanostructure, such as a nano wire, nano ribbon, nanolayer, nanosheet, or the like, hereinafter referred to as a nanolayer. For example, a GAA FET provides a relatively small FET footprint by forming the channel region as a series of vertically stacked nanolayers. In a GAA configuration, a GAA FET includes a source region, a drain region and vertically stacked nanolayer channels between the source and drain regions. These devices typically include one or more suspended nanolayers that serve as the channel. A gate surrounds the stacked nanolayers and regulates electron flow through the nanolayers between the source and drain regions.

GAA FETs may be fabricated by forming alternating layers of active nanolayers and sacrificial nanolayers. The sacrificial nanolayers are released from the active nanolayers before the FET device is finalized. For n-type FETs, the active nanolayers are typically silicon (Si) and the sacrificial nanolayers are typically silicon germanium (SiGe). For p-type FETs, the active nanolayers can be SiGe and the sacrificial nanolayers can be Si. In some implementations, the active nanolayers of a p-type FET can be SiGe or Si, and the sacrificial nanolayers can be Si or SiGe. Forming the nanolayers from alternating layers of active nanolayers formed from a first type of semiconductor material (e.g., Si for n-type FETs, and SiGe for p-type FETs) and sacrificial nanolayers formed from a second type of semiconductor material (e.g., SiGe for n-type FETs, and Si for p-type FETs) may provide for superior channel electrostatics control, which is necessary for continuously scaling or reducing gate lengths.

To further increase the transistor density at given footprint, one can stack one GAA FET over another GAA FET to accommodate high density of transistor at given area. The stacked transistor may be fabricated by a process that may reduce formation of undesired dielectric material build up, sometimes referred to in the art as a neck, after the formation of the bottom source/drain regions. This traditional neck may lead to the utilization of an aggressive etch during the fabrication of frontside source/drain contacts in order to break through the neck and at least partially expose the associated bottom source/drain regions. This aggressive etch may be difficult to manage and may undesirably cause frontside contact to gate shorting.

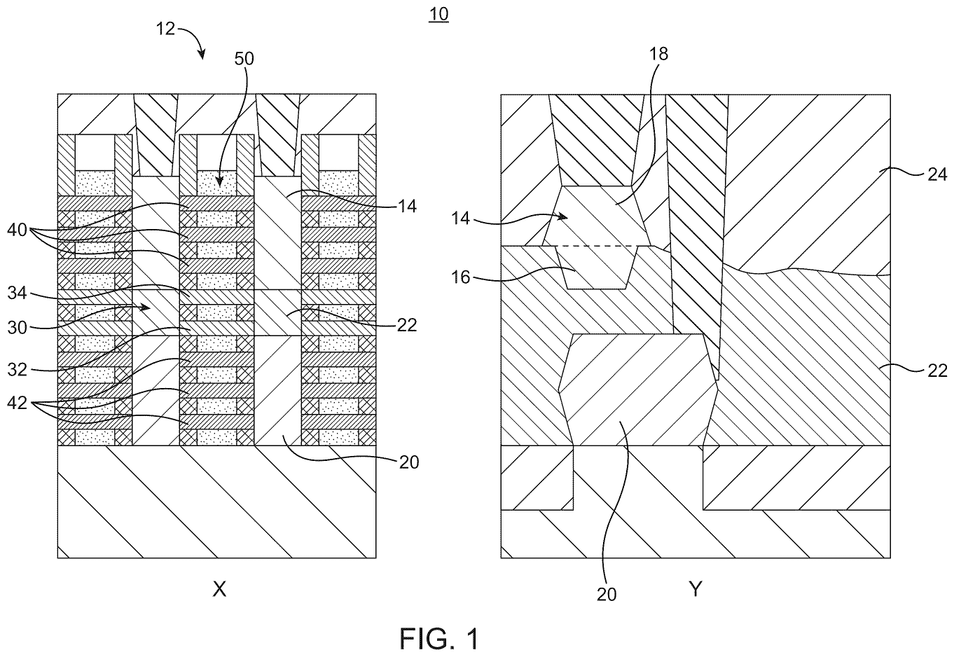

Referring now to FIG. 1, a cross-sectional view of a semiconductor IC device 10 is depicted. In an embodiment of the disclosure an illustrative example of semiconductor IC device 10 is provided. Semiconductor IC device 10 includes a stacked transistor 12. In this example, the stacked transistor 12 includes a top source/drain (S/D) region 14 comprising a lower portion 16 and an upper portion 18. In this example, the stacked transistor 12 further includes a bottom S/D region 20 below the top S/D region 14. In this example, the stacked transistor 12 further includes a bottom interlayer dielectric (ILD) 22 in contact with the bottom S/D region 20 and in contact with the lower portion 16 of the top S/D region 14. In this example, the stacked transistor 12 further includes a top ILD 24 in contact with the upper portion 18 of the top S/D region 14.

In an example, as is illustratively depicted in the Y cross-section view, a largest horizontal dimension of the upper portion 18 of the top S/D region 14 is greater that a largest horizontal dimension of the lower portion 16 of the top S/D region 14. In an example, as is illustratively depicted in the Y cross-section view, a horizontal dimension of the top S/D region 14 is greatest at an interface between the bottom ILD 22 and the top ILD 24.

In an example, the interface between the bottom ILD 22 and the top ILD 24 is substantially horizontally planar. In an example, as is illustratively depicted in the Y cross-section view, the interface between the bottom ILD 22 and the top ILD 24 is non-planar.

In an example, the stacked transistor 12 further includes a multi-layered middle dielectric isolation (MDI) structure 30 comprising a bottom MDI layer 32 and a top MDI layer 34. In an example, the bottom MDI layer 32 is directly connected to the bottom ILD 22 and wherein the top MDI layer 34 is directly connected to the bottom ILD 22.

In an example, the multi-layered MDI structure 30 is between top channels 40 that are directly connected to the top S/D region 14 and bottom channels 42 that are directly connected to the bottom S/D region 20. In an example, the top channels 40, the bottom channels 42, the top MDI layer 34, and the bottom MDI layer 32 have a substantially even/equal vertical thickness.

In an example, the stacked transistor 12 further includes a shared gate structure 50 around each of the top channels 40, around each of the bottom channels 42, around the top MDI layer 34, and around the bottom MDI layer 32.

In another embodiment of the disclosure, an illustrative example of semiconductor IC device 10 is provided that includes another stacked transistor 12. In this example, the stacked transistor 12 includes the top source/drain (S/D) region 14 comprising the lower portion 16 and the upper portion 18. Further, in this example, the stacked transistor 12 includes the bottom interlayer dielectric (ILD) 22 in contact with the lower portion 16 of the top S/D region 14. Further, in this example, the stacked transistor 12 includes the top ILD 24 in contact with the upper portion 18 of the top S/D region 14.

In another embodiment of the disclosure, an illustrative example of semiconductor IC device 10 is provided that includes a second stacked transistor 12. In this example, the stacked transistor 12 includes the bottom S/D region 20, the top S/D region 14 that is offset from the bottom S/D region 20, the top S/D region 14 comprising the lower portion 16 that is inset relative to the upper portion 18, and an interlayer dielectric (ILD), such as the bottom ILD 22. In this example, the upper portion 18 of the top S/D region 14 comprises a bottom surface that is substantially coplanar with a top surface of the ILD.

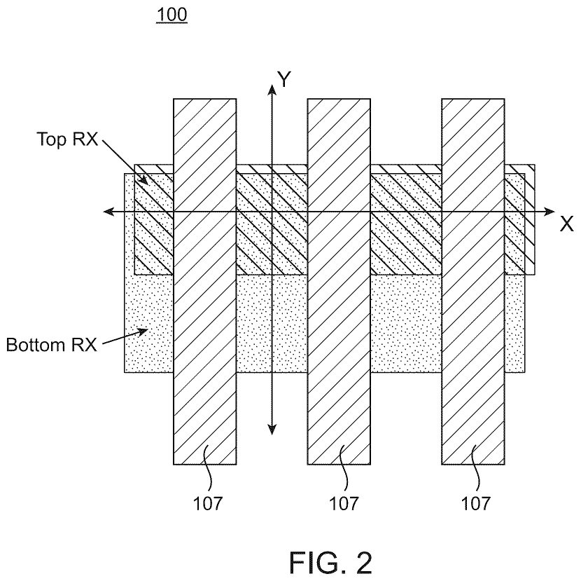

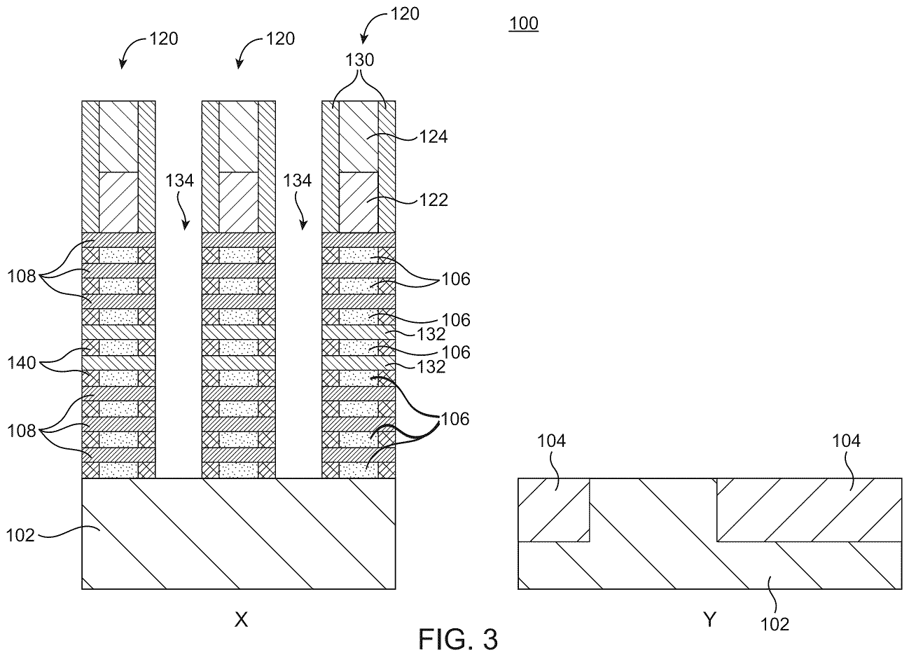

FIG. 2 depicts a partial top-down structure view of a semiconductor IC device 100 and establishes an illustrative X cross-sectional plane and a Y cross-sectional plane. The X cross-sectional plane is through a bottom active region (RX), a top RX that is offset relative to the bottom RX, and across gate structures 107. The Y cross-sectional plane is through bottom RX, through top RX, and between adjacent gate structures 107. For clarity, the partial top-down structure views of the semiconductor IC device(s) that establish X cross-sectional plane and Y cross-sectional plane are repeated in FIG. 3 through FIG. 12, the description(s) of which are not repeated herein.

FIG. 3 depicts a cross-sectional view of the semiconductor IC device 100 after initial fabrication operations, in accordance with embodiments of the present disclosure. In these initial fabrication stages, semiconductor IC device 100 may include a substrate structure 102, shallow trench isolation regions 104, sacrificial nanolayers 106, active nanolayers 108, sacrificial gate structures 120, gate spacers 130, MDI layers 132, inner spacers 140. For clarity, the fabrication of the semiconductor IC device 100 at the present stage may utilize processes that may now be known or that may be developed in the future.

For illustration and enablement purposes, a particular fabrication process to form semiconductor IC device 100 at the present stage is presented below. This illustrative methodology may be one of many that may achieve or result in the initial semiconductor IC device 100, as depicted. When components referenced in the illustrative methodology below are depicted in FIG. 3, such associated component numeral is expressly utilized. Otherwise, when components are referenced in the illustrative methodology that are not depicted in FIG. 3, a component numeral is not denoted.

In the initial fabrication stages, nanolayers may be formed upon the substrate structure 102. The substrate structure 102 may be a bulk-semiconductor substrate. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon (Si) is the predominantly used semiconductor material in wafer fabrication, alternative semiconductor materials can be employed, such as, but not limited to, gallium arsenide, gallium nitride, cadmium telluride, zinc selenide, and III-V compound semiconductors and/or II-VI compound semiconductors. III-V compound semiconductors are materials that include at least one element from Group III of the Periodic Table of Elements and at least one element from Group V of the Periodic Table of Elements. II-VI compound semiconductors are materials that include at least one element from Group II of the Periodic Table of Elements and at least one element from Group VI of the Periodic Table of Elements.

The substrate structure 102 may include an upper substrate, a lower substrate, and an etch stop layer between the upper substrate and the lower substrate. The upper substrate and the lower substrate may be comprised of any other suitable material(s) that those listed above and the etch stop layer may be a dielectric material with etch selectivity to one or both of the upper substrate and/or the lower substrate. In one example, the etch stop layer may be an oxide and the substrate structure 102 may be referred to as a buried oxide (BOX) substrate. The etch stop layer can also be an epitaxial SiGe layer grown from substrate and the upper substrate can also be an epitaxial Si layer grown from etch stop layer.

The nanolayers may be formed over the substrate structure 102 by forming a first series of alternating blanket layers of sacrificial nanolayers 106 and active nanolayers 108. In certain examples, the first sacrificial nanolayer 106 material is initially formed directly on an upper surface of the substrate structure 102. In other examples, certain layer(s) may be formed between the upper surface of the substrate structure 102 and the first one of the sacrificial nanolayers 106. In an example, each sacrificial nanolayer 106 is composed of silicon-germanium (e.g., SiGe, where the Ge ranges from about 20-30%).

Next, a blanket layer of active nanolayer 108 material is formed on an upper surface of the first one of the sacrificial nanolayers 106. In an example, the active nanolayer 108 is composed of silicon. One or more additional blanket layers of the sacrificial nanolayers 106 and active nanolayers 108 may be alternately formed in the first series of alternating nanolayers. In the illustrated semiconductor IC device 100, there are a total of three sacrificial nanolayers 106 and three active nanolayers 108 in the first series of alternating nanolayers. However, it should be appreciated that any suitable number of alternating nanolayers may be formed.

The nanolayers may be further formed over the first series of nanolayers by forming an intermediary series of alternating blanket layers of MDI sacrificial nanolayers and sacrificial nanolayers 106. In certain examples, a first MDI sacrificial nanolayer is initially formed directly on an upper surface of the first series of nanolayers. In an example, each MDI sacrificial nanolayer is composed of silicon-germanium (e.g., SiGe, where the Ge ranges from about 55-65%).

Next, a blanket layer of sacrificial nanolayer 106 material is formed on an upper surface of the first MDI sacrificial nanolayer. In an example, the sacrificial nanolayer 106 is composed of silicon-germanium (e.g., SiGe, where the Ge ranges from about 35-45%). An additional MDI sacrificial nanolayer may be formed in the intermediary series of alternating blanket layers. In the illustrated semiconductor IC device 100, there are a total of two MDI sacrificial nanolayers and one sacrificial nanolayer 106 in the intermediary series of alternating blanket nanolayers. However, it should be appreciated that any suitable number of alternating nanolayers may be formed. For example, four or more MDI sacrificial nanolayers may be formed with a sacrificial nanolayer 106 formed therebetween in the intermediary series of alternating blanket nanolayers.

The nanolayers may be further formed by forming a second series of alternating blanket layers of sacrificial nanolayers 106 and active nanolayers 108. In certain examples, the first sacrificial nanolayer 106 of the second series of alternating nanolayers is initially formed directly on an upper surface of the intermediary series of alternating blanket nanolayers.

Next, a blanket layer of active nanolayer 108 material is formed on an upper surface of the first one of the sacrificial nanolayers 106 of the second series of alternating nanolayers. One or more additional blanket layers of the sacrificial nanolayers 106 and active nanolayers 108 may be alternately formed in the second series of alternating nanolayers. In the illustrated semiconductor IC device 100, there are a total of three sacrificial nanolayers 106 and three active nanolayers 108 in the second series of alternating nanolayers. However, it should be appreciated that any suitable number of alternating nanolayers may be formed.

Although it is specifically contemplated that the sacrificial nanolayers 106 and the in the MDI sacrificial nanolayers can be formed from SiGe and that the blanket active nanolayers 108 can be formed from Si, it should be understood that any appropriate materials can be used instead, as long as the semiconductor materials have etch selectivity with respect to one or more of the others, as is consistent with the description of the fabrication stages herein.

The alternating blanket nanolayers can be deposited by any appropriate mechanism. The alternating blanket nanolayers can be epitaxially grown from one another, but alternate deposition processes, such as chemical vapor deposition (CVD), physical vapor deposition (PVD), atomic layer deposition (ALD), or gas cluster ion beam (GCIB) deposition, are also contemplated.

In certain embodiments, each of the one or more of the blanket nanolayers has a vertical thickness ranging, for example, from approximately 3 nm to approximately 20 nm. In certain embodiments, the blanket nanolayers have a vertical thickness ranging, for example, from approximately 3 nm to approximately 10 nm. Although the range of 3-20 nm is cited as an example range of thickness of the sacrificial blanket nanolayers, other thickness of these nanolayers may be used.

In the initial fabrication stages, the nanolayers may be patterned into nanolayer stacks and shallow trench isolation (STI) regions 104 may be formed. To form one or more nanolayer stacks, a mask layer (not shown) is formed on the uppermost nanolayer. The mask layer may be comprised of any suitable mask material(s). The mask layer may be patterned and used to perform the nanolayer stack patterning process. In the nanolayer stack patterning process, any suitable material removal process (e.g., reactive ion etching or RIE) may be used to remove portions of the alternating nanolayers down to the level of the substrate structure 102, or the like. Following the nanolayer stack patterning process, one or more nanolayer stacks are formed. Subsequently, the mask layer may be removed.

The removal of undesired portion(s) of the alternating nanolayers may further remove undesired portions of substrate structure 102 that are adjacent to respective footprints of nanolayer stacks to form STI region openings. The etch may be timed or otherwise controlled to stop the removal of the substrate structure 102 such that the depth or bottom of the one or more STI region openings has a predetermined or desired dimension. For example, the depth or bottom of the one or more STI region openings may be above the etch stop layer. In some examples, the etch to form the nanolayer stacks may utilize the etch stop layer to stop the etch and form the bottom of the one or more STI region openings.

A STI region 104 may be formed upon the substrate structure 102 below and adjacent to the nanolayer stacks within the STI region openings. For example, one or more STI regions 104 may be formed by depositing electrical dielectric material(s) within the STI region openings adjacent to the one or more nanolayer stacks. A top surface of the one or more STI regions 104 may be coplanar with a top surface of substrate structure 102. The one or more STI regions 104 may have a volume that sufficiently electrically isolates components or features of neighboring transistors, or the like, and/or may sufficiently electrically isolate neighboring nanolayer stacks.

In an example, the STI region(s) 104 may be formed by depositing a STI liner within the STI region openings adjacent to the footprint of nanolayer stacks. Subsequently, STI region(s) 104 may be further formed by depositing STI dielectric material upon the STI liner. An etch back, recess, or the like, may be performed to remove undesired or over formed STI liner and/or STI dielectric material such that the top surface of the STI region(s) 104 is coplanar with a bottom surface of the bottom most sacrificial nanolayer 106. Exemplary materials for the STI liner may be SiN, or the like. Exemplary materials for the STI dielectric may be SiO₂, low-k oxide, or the like.

In the initial fabrication stages, one or more sacrificial gate structures 120 are formed upon STI regions 104 and upon and around the one or more nanolayer stacks. The one or more sacrificial gate structures 120 may include a sacrificial gate liner (not shown), a sacrificial gate 122, and a sacrificial gate cap 124.

The sacrificial gate structures 120 may be formed by initially depositing a sacrificial gate liner layer (e.g., a dielectric, oxide, or the like) upon the one or more STI regions 104 and upon and around the one or more nanolayer stacks. The sacrificial gate structures 120 may further be formed by subsequently depositing a sacrificial gate layer (e.g., amorphous silicon, or the like) upon the sacrificial gate liner layer. The thickness of the sacrificial gate layer may be such that the top surface of the sacrificial gate layer is above the top surface of the one or more nanolayer stacks. The sacrificial gate structures 120 may further be formed by forming a gate cap layer upon the sacrificial gate layer. The gate cap layer may be formed by depositing a mask material, such as a hard mask material, such as silicon nitride, silicon oxide, combinations thereof, or the like, upon the sacrificial gate layer. The gate cap layer may be composed of one or more layers of masking materials to protect the sacrificial gate layer and/or other underlying materials during subsequent processing of semiconductor IC device 100.

The one or more sacrificial gate structures 120 may further be formed by patterning the gate cap layer, sacrificial gate layer, and sacrificial gate liner by, for example, using lithography and etch processes to remove undesired portions and retain desired portion(s), respectively. The retained desired portion(s) of the gate cap layer, sacrificial gate layer, and sacrificial gate liner may form the sacrificial gate liner (not shown), the sacrificial gate 122, and the sacrificial gate cap 124, respectively, of each of the one or more sacrificial gate structures 120.

One or more sacrificial gate structures 120 can be formed on targeted regions or areas of semiconductor IC device 100 to define the length of one or more GAA FETs and to provide sacrificial material for yielding targeted GAA FET structure(s) in subsequent processing.

The MDI sacrificial nanolayers may be selectively removed by a wet etch utilizing an etchant that targets the material of the MDI sacrificial nanolayers selective to the respective material(s) of the sacrificial nanolayers 106, the active nanolayers 108, STI region(s) 104, and sacrificial gate structures 120. The etch may be timed or otherwise controlled to effectively remove the MDI sacrificial nanolayers while substantially retaining the sacrificial nanolayers 106, the active nanolayers 108, STI region(s) 104, and sacrificial gate structures 120, etc. The removal of MDI sacrificial nanolayers forms one or more respective MDI nanolayer cavities between sacrificial nanolayers 106.

In the initial fabrication stages, gate spacers 130 and MDI layers 132 may be formed. The MDI layers 132 are formed within a respective MDI nanolayer cavity. The gate spacer(s) 130 are formed upon the sidewall(s) of the sacrificial gate cap 124 and sacrificial gate 122, upon the STI region(s) 104, and around the one or more nanolayer stacks.

The MDI layers 132 and the gate spacer(s) 130 may be simultaneously formed by a conformal deposition of a dielectric material, such as silicon nitride, SiBCN, SiNC, SiN, SiCO, SiNOC, or a combination thereof, or the like, within the MDI nanolayer cavities, upon STI regions 104, upon and around the one or more sacrificial gate structures 120, and upon and around the one or more nanolayer stack(s). Subsequently, undesired portions dielectric material may be removed while desired portions the dielectric material may be retained and thereby form the MDI layers 132 and the gate spacer(s) 130. The undesired portions of dielectric material may be removed by a directional ion etch, such as a reactive ion etch (RIE). The RIE may remove exposed or unprotected horizontal portions of the dielectric material while retaining protected horizontal portions of the dielectric layer and vertical portions of the dielectric layer.

In the initial fabrication stages, source/drain (S/D) recesses 134 are formed within the one or more nanolayer stacks between gate spacers 130 that are associated with neighboring sacrificial gate structures 120. In other words, a single nanolayer stack may be separated into multiple nanolayer stacks, each located underneath a sacrificial gate structure 120, by the formation of one or more S/D recesses 134.

The one or more S/D recesses 134 may be formed between adjacent sacrificial gate structures 120 by removing respective portions of the sacrificial nanolayers 106, active nanolayers 108, MDI layers 132, that are between gate spacers 130 of adjacent or neighboring sacrificial gate structures 120. The one or more S/D recesses 134 may be formed to a depth to stop at the top surface of substrate structure 102 (e.g., the top surface of upper substrate, or the like). In the separation of the nanolayer stack into multiple nanolayer stacks, respective portions of the sacrificial nanolayers 106, active nanolayers 108, MDI layers 132 that are located below the gate spacers 130 and below the sacrificial gate structures 120 may be retained.

As the gate spacers 130 and the sacrificial gate structures 120 may be utilized to protect the underlying portions of sacrificial nanolayers 106, active nanolayers 108, MDI layers 132, respective sidewalls of the nanolayer stacks may be substantially coplanar with the outer sidewalls of the gate spacers 130 there above.

In the initial fabrication stages, indents may formed by laterally or horizontally removing respective portions of sacrificial nanolayers 106. The indents may be formed by a reactive ion etch (RIE) process, a wet etch process, which can remove portions of the sacrificial nanolayers 106. The horizontal depth of the indents may be chosen to set a length for the replacement gate structure formed in place of the sacrificial gate structure 120. When the sacrificial nanolayers 106 are composed of SiGe, an isotropic etch process can use a boron-based chemistry or a chlorine-based chemistry, for example, which recesses or removes the exposed end portions of sacrificial nanolayers 106 (e.g., end portions of sacrificial nanolayers 106 generally below spacer 130, etc.) selective to the Si active nanolayers 108. In alternative implementations when sacrificial nanolayers 106 are not SiGe and when active nanolayers 108 are not Si, an isotropic etch process of the sacrificial nanolayers 106 may generally be selective to the active nanolayers 108, gate spacers 130, STI regions 104, and/or substrate structure 102.

In the initial fabrication stages, a respective inner spacer 140 is formed within each of the one or more indents. The one or more inner spacers 140 can be formed by ALD or CVD or any other suitable deposition technique that deposits a dielectric material within the indents. In some examples, the inner spacer(s) 140 are composed of a low-κ dielectric material (a material with a lower dielectric constant relative to SiO₂), SiN, SiO, SiBCN, SiOCN, SiCO, etc. or any other suitable dielectric material. In certain implementations, after the formation of the inner spacer(s) 140, an isotropic etch process is performed to create outer vertical surfaces of the inner spacer(s) 140 that are coplanar with outer vertical surfaces of the active nanolayers 108 and/or of the gate spacers 130.

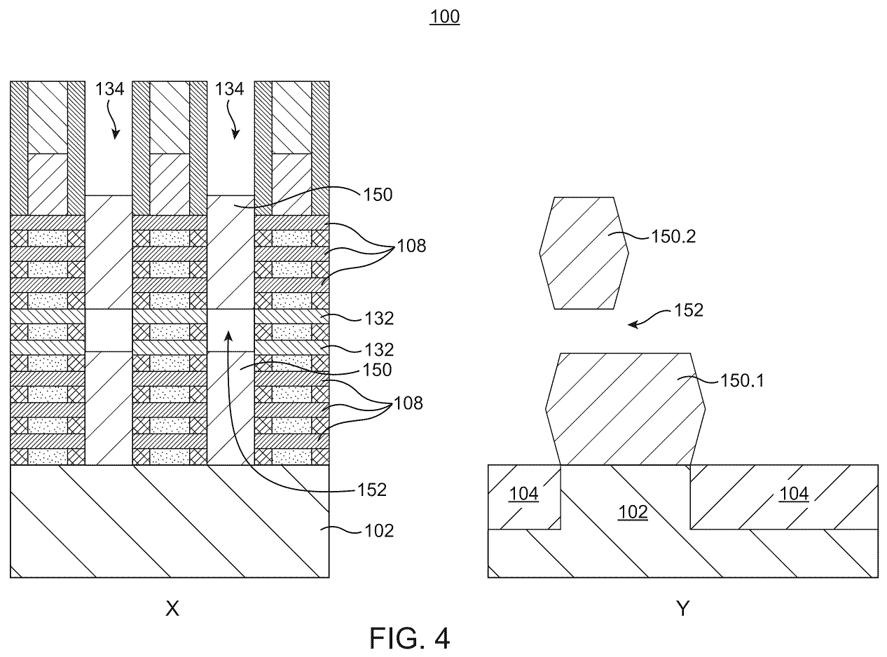

The multiple MDI layers 132 advantageously provides for relatively increased separation between the top FET and the bottom FET. Further, the multiple MDI layers 132 increases the process margin associated with process variation control of the formation of the S/D region 150, as depicted in FIG. 4. For example, the multiple MDI layers 132 improves CMP center/edge uniformity, ILD recess non-uniformity, etc. as opposed to a single layer MDI where such process margins are relatively smaller. Similarly, the multiple MDI layers 132 may assist in preventing the S/D regions 150, as depicted in FIG. 4, within the same S/D recesses 134 from merging. In other words, the multiple MDI layers 132 help to ensure a gap is maintained between an upper S/D region 150 and a lower S/D region 150, as depicted in FIG. 4.

FIG. 4 depicts cross-sectional views of the semiconductor IC device 100 after fabrication operations, in accordance with embodiments of the present disclosure. In the depicted fabrication stages, S/D regions 150 may be formed.

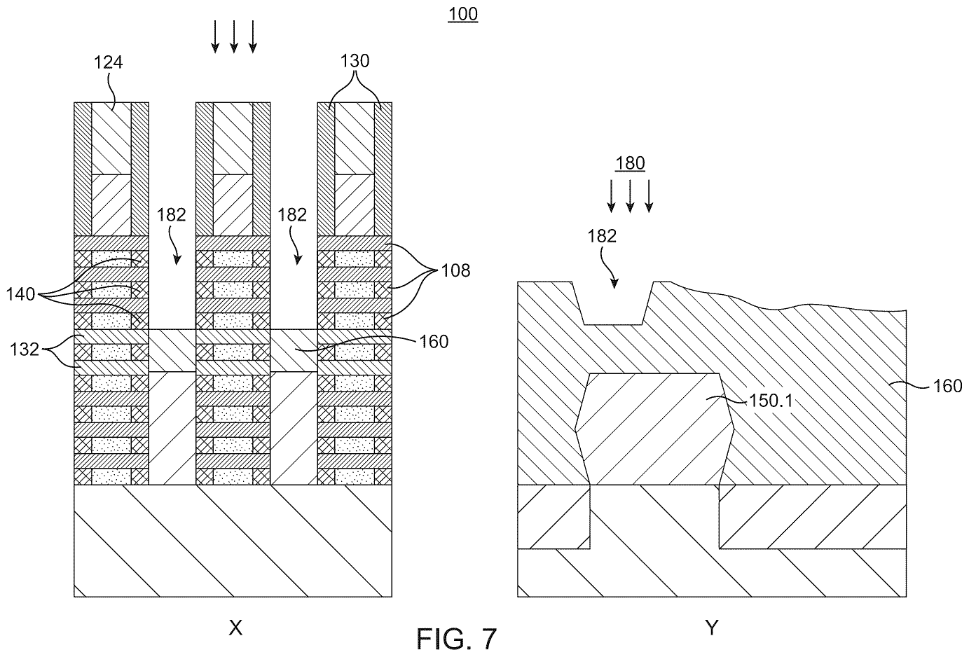

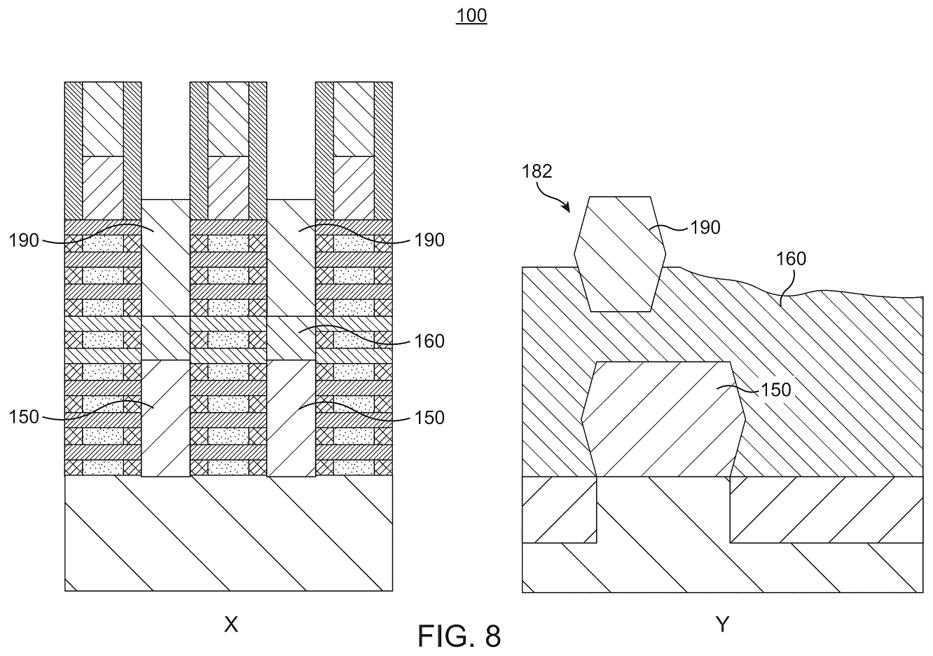

The S/D regions 150 may be formed upon the substrate structure 102 and upon sidewalls of neighboring nanolayer stacks, respectively. For clarity, a bottom S/D region 150.1 and a top S/D region 150.2 are depicted. The bottom S/D region 150.1 forms either a source or a drain, respectively, of respective bottom GAA FET and is connected to respective side or end surfaces of active nanolayers 108 thereof. At the current fabrication stage, top S/D region 150.2 may be a sacrificial top S/D region that may be removed and replaced by a S/D region of opposite type. For example, if the S/D regions 150 are p-type S/D regions, the top S/D region 150.2 may be later removed and replaced by a n-type S/D region, for example, as depicted in FIG. 7 and in FIG. 8.

Each of the S/D regions 150 is composed of a semiconductor material and a dopant. As used herein, a “source/drain” region can be a source region or a drain region depending on subsequent wiring and application of voltages during operation of the transistor. The semiconductor material that provides each of the S/D regions 150 is composed of one of the semiconductor materials mentioned above for the substrate structure 102. The semiconductor material that provides the S/D regions 150 can be compositionally the same, or compositionally different from each active nanolayers 108. The dopant that is present in the S/D regions 150 can be either a p-type dopant or an n-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium, phosphorus and indium. The term “n-type” refers to the addition of impurities that contributes free electrons to an intrinsic semiconductor. In a silicon-containing semiconductor material, examples of n-type dopants, i.e., impurities, include, but are not limited to, antimony, arsenic and phosphorous.

The S/D regions 150 may be epitaxially grown or formed. The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases are controlled and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed. For example, an epitaxially grown semiconductor material deposited on a (100) orientated crystalline surface will take on a (100) orientation. In some embodiments, epitaxial growth and/or deposition processes are selective to forming on semiconductor surfaces, and generally do not deposit material on exposed surfaces, such as silicon dioxide or silicon nitride surfaces. In some examples, the S/D regions 150 are formed by in-situ doped epitaxial growth. The use of an in-situ doping process is merely an example. For instance, one may instead employ an ex-situ process to introduce dopants into the source and drains. Other doping techniques can be used to incorporate dopants in the bottom source/drain region. Dopant techniques include but are not limited to, ion implantation, gas phase doping, plasma doping, plasma immersion ion implantation, cluster doping, infusion doping, liquid phase doping, solid phase doping, in-situ epitaxy growth, or any suitable combination of those techniques. In examples, the S/D epitaxial growth conditions promote in-situ Boron doped SiGe for p-type transistor and phosphorus or arsenic doped silicon or Si: C for n-type transistors.

In some examples, the S/D epitaxial growth that forms the one or more S/D region 150.1 occurs or is promoted from the top surface of the substrate structure 102 and from the exposed sidewalls of the active nanolayers 108 that are below the MDI layers 132, while epitaxial growth is limited or does not occur from neighboring STI regions 104. Similarly, the S/D epitaxial growth that forms the one or more S/D region 150.2 occurs or is promoted from the exposed sidewalls of the active nanolayers 108 that are above the MDI layers 132, while epitaxial growth is limited or does not occur from neighboring STI regions 104. For clarity, because of the MDI layers 132 a gap 152 may be maintained between the top S/D region 150.2 and the bottom S/D region 150.1 during the S/D region 150 formation.

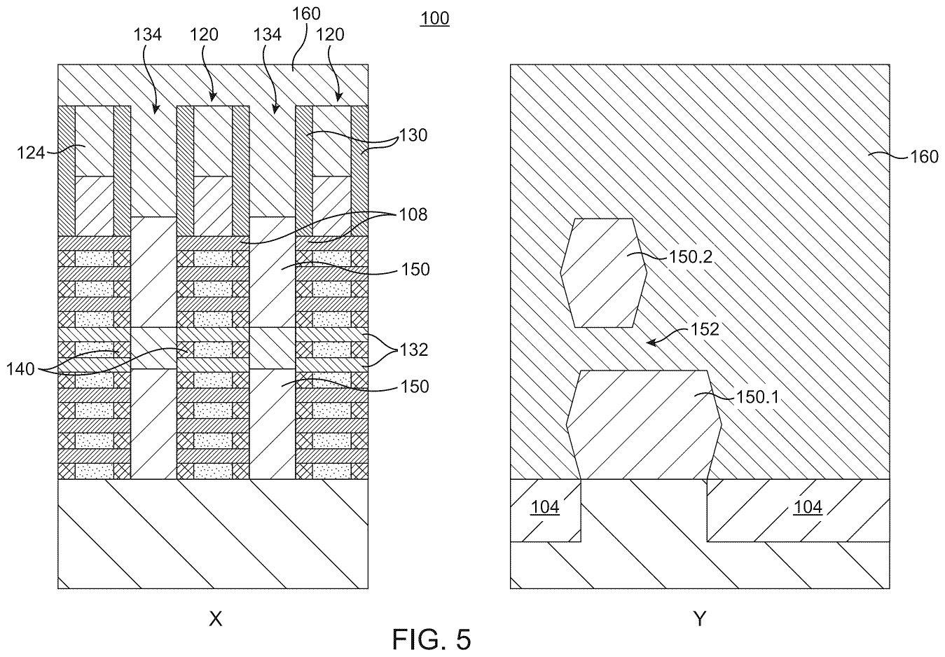

FIG. 5 depicts cross-sectional views of the semiconductor IC device 100 after fabrication operations, in accordance with embodiments of the present disclosure. In the depicted fabrication stages, an interlayer dielectric (ILD) 160 may be formed. For example, ILD 160 may be formed upon the STI regions 104, upon and around the bottom S/D region 150.1, upon and around the top S/D region 150.2, within the S/D recesses 134 upon the associated sidewalls of the MDI layers 132 and the associated inner spacers 140, upon the gate spacers 130, and upon the sacrificial gate caps 124 of the sacrificial gate structures 120.

The ILD 160 may be formed by depositing a blanket dielectric material. The ILD 160 can be any suitable material, such as, for example, porous silicates, carbon doped oxides, silicon dioxides, silicon nitrides, silicon oxynitrides, organic planarization material (OPL), or other dielectric materials. Any known manner of forming the ILD 160 can be utilized. The ILD 160 can be formed using, for example, CVD, PECVD, ALD, flowable CVD, spin-on dielectrics, or PVD. In a particular example, ILD 160 may be a conformal low temperature oxide, such as an iRAD SiO₂. The low temperature and conformal deposition process may minimize dopant diffusion from the top S/D region 150.2 into the associated active nanolayers 108 that are in contact therewith while also adequately filling the gap 152 between the top S/D region 150.2 and the bottom S/D region 150.1. In an example, the ILD 160 may be formed to a thickness above the top surface of the sacrificial gate structures 120.

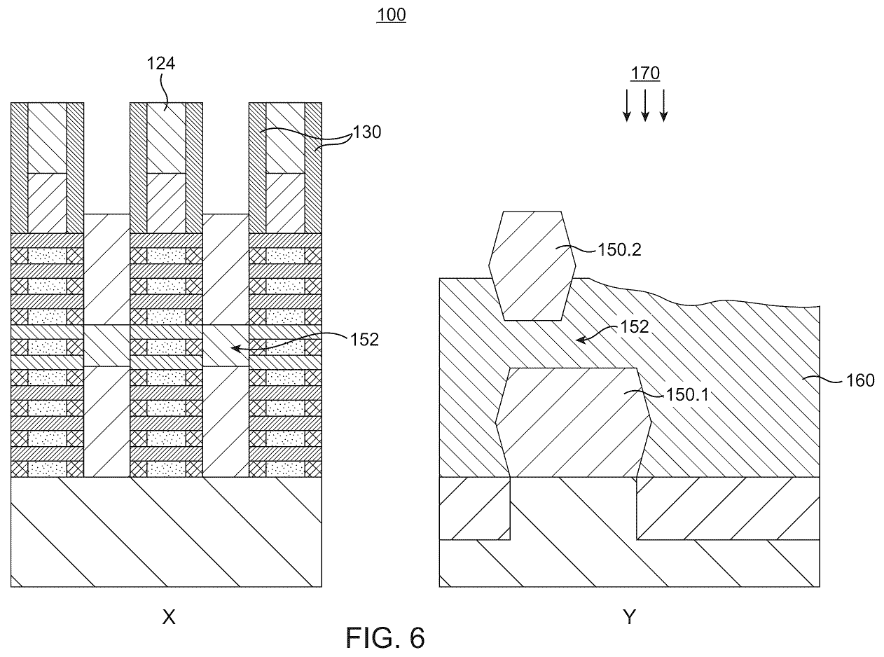

FIG. 6 depicts cross-sectional views of the semiconductor IC device 100 after fabrication operations, in accordance with embodiments of the present disclosure. In the depicted fabrication stages, the ILD 160 may be partially recessed to expose the top S/D region 150.2.

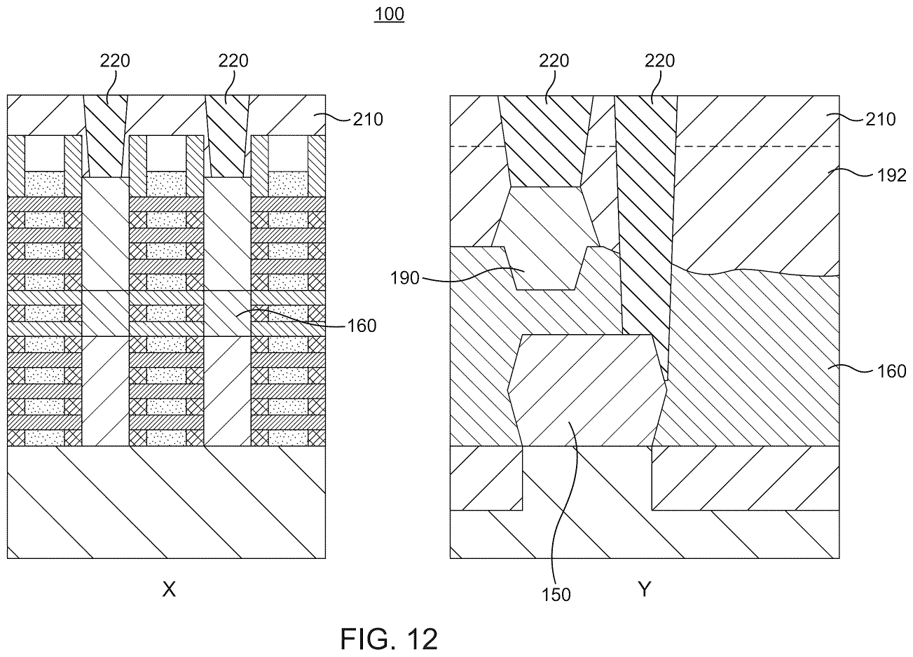

The ILD 160 may be partially recessed by a subtractive removal technique 170, such as a selective etch. The etch may remove the material of the ILD 160 selective to the respective materials of the top S/D region 150.2, of the gate spacers 130, of the sacrificial gate cap 124, or the like. At least an upper portion of the top S/D region 150.2 may be exposed as a result of the partial recess of the ILD 160. For example, the etch may be timed or otherwise controlled so that the upper surface of the ILD 160 is inset or between an upper surface and lower surface of the top S/D region 150.2. As depicted, the etch of the ILD 160 need not be perfectly uniform or precisely controlled to create a substantially horizontal upper surface of the ILD 160. For clarity, the ILD 160 formation process allows for excess material build up or material necking within gap 152 to be minimized, which may allow for more reliable frontside contact formation to the bottom S/D region 150.1, as depicted in FIG. 12.

FIG. 7 depicts cross-sectional views of the semiconductor IC device 100 after fabrication operations, in accordance with embodiments of the present disclosure. In the depicted fabrication stages, the top S/D regions 150.2 may be removed.

The top S/D regions 150.2 may be removed by a subtractive removal technique 180, such as a selective etch. The etch may remove the top S/D regions 150.2 selective to the respective materials of the ILD 160, of the gate spacers 130, of the sacrificial gate cap 124, of the active nanolayers 108, of the inner spacers 140, or the like. The removal of the top S/D regions 150.2 may form a concave bowl 182 within the ILD 160 and above a respective bottom S/D region 150.1. The concave bowl 182 may generally or substantially take the negative or receptacle form of the perimeter of the top S/D region 150.2 previously associated therewith. The removal of the top S/D regions 150.2 may expose the ends or sidewalls of the active nanolayers 108 that are located above the MDI layers 132. Because top S/D region 150 have been removed, the previously associated bottom S/D regions 150.2 may be now referred to herein as bottom S/D regions 150.

FIG. 8 depicts cross-sectional views of the semiconductor IC device 100 after fabrication operations, in accordance with embodiments of the present disclosure. In the depicted fabrication stages, top S/D regions 190 may be formed.

The top S/D regions 190 may be formed upon sidewalls of the active nanolayers 108 that are located above the MDI layers 132. Each top S/D region 190 forms either a source or a drain, respectively, of respective one or more top GAA FETs and is connected to respective side or end surfaces of active nanolayers 108 thereof. Each of the top S/D region 190 is composed of a semiconductor material and a dopant. The semiconductor material that provides each of the top S/D region 190 is composed of one of the semiconductor materials mentioned above for the substrate structure 102. The semiconductor material that provides the top S/D region 190 can be compositionally the same, or compositionally different from each active nanolayers 108. The dopant that is present in the top S/D region 190 can be either a p-type dopant or an n-type dopant. In a particular example, the dopant type within the top S/D regions 190 may be the opposite type relative to the dopant type within the bottom S/D regions 150.

The one or more top S/D regions 190 may be epitaxially grown or formed. In some examples, the one or more top S/D region 190 are formed by in-situ doped epitaxial growth. The use of an in-situ doping process is merely an example. For instance, one may instead employ an ex-situ process to introduce dopants into the source and drains. Other doping techniques can be used to incorporate dopants in the top S/D region 190.

The top S/D region 190 may be formed to a thickness above the top surface of the topmost active nanolayer 108 and below the bottom surface of the bottom most active nanolayer 108 within the second series of nanolayers (i.e., those active nanolayers 108 above the MDI layers 132). The top S/D region 190 may be formed within the concave bowl 182 of the ILD 160. The formation or epitaxial growth of top S/D region 190 may further partially occur outside of the concave bowl 182 of the ILD 160 and may form an extension region or lip upon the ILD 160 outside of the concave bowl 182, as depicted.

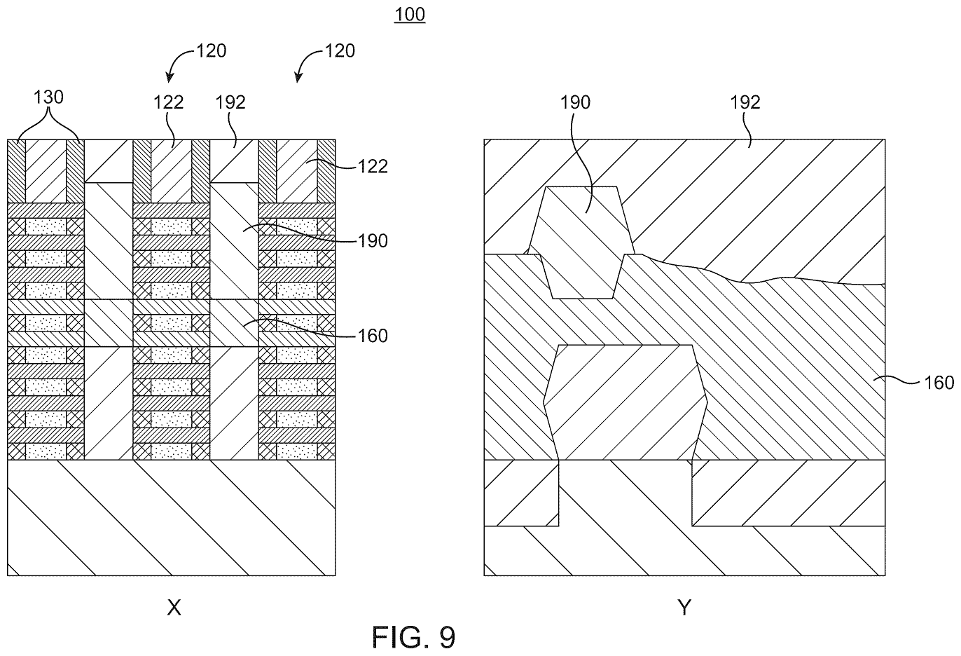

FIG. 9 depicts cross-sectional views of the semiconductor IC device 100 after fabrication operations, in accordance with embodiments of the present disclosure. In the depicted fabrication stages, top ILD 192 may be formed.

The ILD 192 may be formed upon respective top surfaces of replacement gate structures 120, upon the top S/D regions 190, and upon ILD 160. The ILD 192 may be formed by depositing a dielectric material, such as, for example, porous silicates, carbon doped oxides, silicon dioxides, silicon nitrides, silicon oxynitrides, or other dielectric materials. Any appropriate deposition technique for forming the ILD 192 can be utilized. The ILD 192 can be formed using, for example, CVD, PECVD, ALD, flowable CVD, spin-on dielectrics, or PVD. The ILD 192 may be the same material(s) as the ILD 160 or may be relatively different material(s).

Subsequently, a planarization process, such as a CMP, may be performed to remove excess ILD 192 material and to remove the sacrificial gate caps 124 of the sacrificial gate structures 120, thereby exposing the sacrificial gate 122 thereunder. The planarization may also partially remove some of the sacrificial gate 122 or may at least expose the sacrificial gate 122 of the sacrificial gate structures 120. Consequently, respective top surfaces of the gate spacers 130, the sacrificial gate 122, and the ILD 192 may be substantially horizontal and/or substantially coplanar.

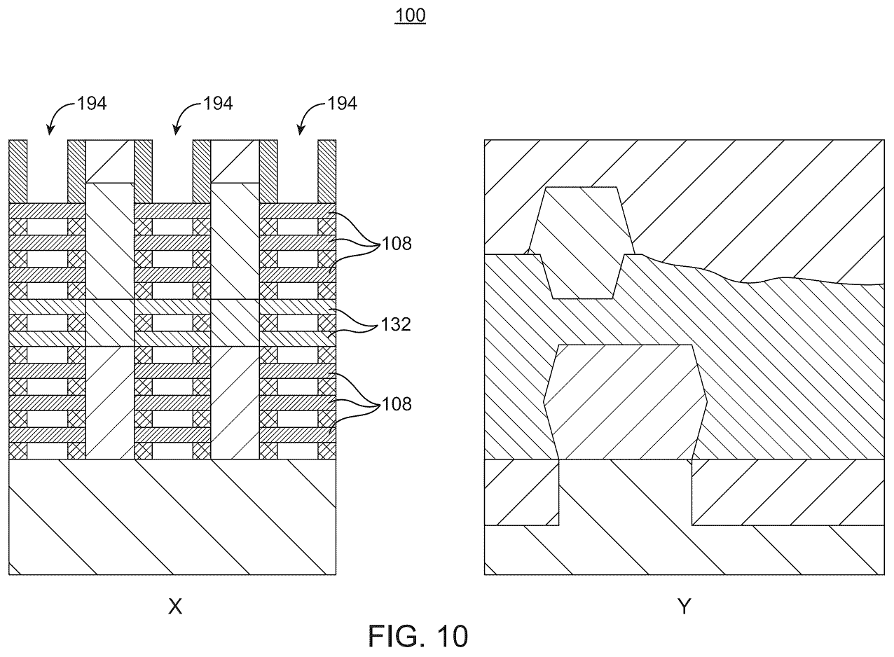

FIG. 10 depicts cross-sectional views of the semiconductor IC device 100 after fabrication operations, in accordance with embodiments of the present disclosure. In the depicted fabrication stages, the sacrificial gate structures 120 and the sacrificial nanolayers 106 may be removed, thereby forming respective replacement gate openings 194.

The sacrificial gate structures 120 may be removed by initially removing the sacrificial gate 122 and sacrificial gate oxide by a removal technique, such as one or more series of etches. For example, such removal may be accomplished by an etching process which may include a dry etching process such as RIE, plasma etching, ion etching or laser ablation. The etching can further include a wet chemical etching process in which one or more chemical etchants are used to remove the sacrificial gate 122 and sacrificial gate oxide. Appropriate etchants may be used that remove the sacrificial gate 122 and/or sacrificial gate oxide selective to the active nanolayers 108, inner spacers 140, gate spacers 130, STI regions 104, MDI layers 132, and substrate structure 102, or the like.

The replacement gate openings 194 may be further formed by releasing the active nanolayers 108 by removing the sacrificial nanolayers 106. The sacrificial nanolayers 106 may be removed by a removal technique, such as one or more series of etches. For example, the etching can include a wet chemical etching process in which one or more chemical etchants are used to remove the sacrificial nanolayers 106. Appropriate etchants may be used that remove the sacrificial nanolayers 106 selective to the active nanolayers 108, inner spacers 140, gate spacers 130, MDI layers 132, or the like. After the removal of sacrificial nanolayers 106, there are void spaces associated with the active nanolayers 108. Similarly, after the removal of sacrificial nanolayers 106, there may be a void space associated with the MDI layers 132.

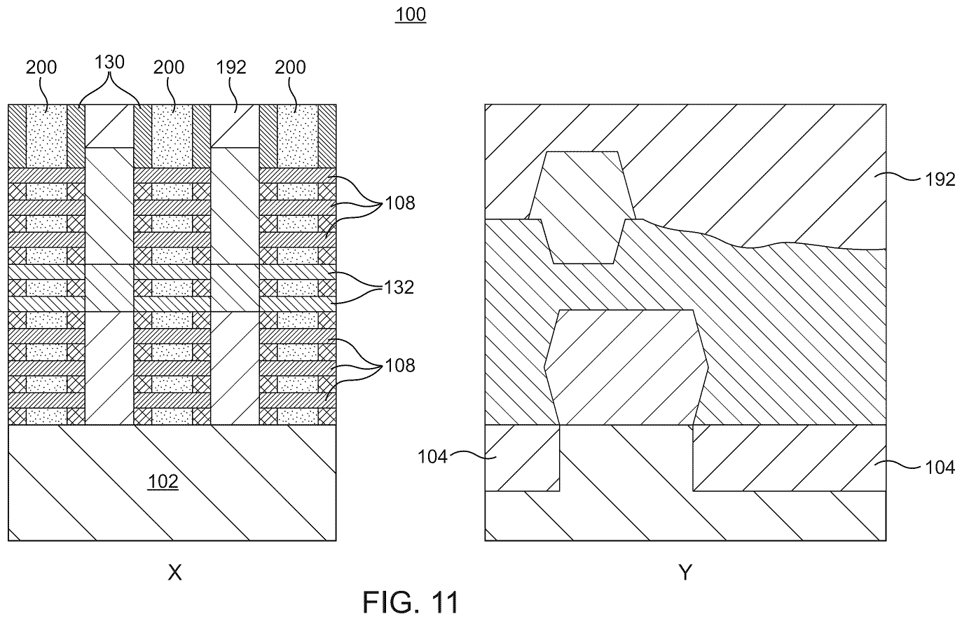

FIG. 11 depicts cross-sectional views of the semiconductor IC device 100 after fabrication operations, in accordance with embodiments of the present disclosure. In the depicted fabrication stages, a replacement gate structure 200 is formed within the replacement gate openings 194. The replacement gate structure 200 may be formed around the active nanolayers 108 and around the MDI layers 132.

Replacement gate structure(s) 200 may be formed by initially forming an interfacial layer on the gate spacer 130, on the active nanolayers 108, on the MDI layers 132, and on the inner spacers 140, etc. that are interior to and/or upon the respective surfaces interior to the replacement gate opening(s) 194. The interfacial layer can be deposited by any suitable techniques, such as ALD, CVD, PVD, thermal oxidation, combinations thereof, or other suitable techniques.

Replacement gate structure(s) 200 may be further formed by forming a high-κ layer to cover the exposed surfaces of the interfacial layer. The high-κ layer can be deposited by any suitable techniques, such as ALD, CVD, metal-organic CVD (MOCVD), PVD, thermal oxidation, combinations thereof, or other suitable techniques. A high-κ material is a material with a higher dielectric constant than that of SiO₂, and can include e.g., LaO, AlO, ZrO, TiO, Ta₂O₅, Y₂O₃, SrTiO₃(STO), BaTiO₃ (BTO), BaZrO, HfZrO, HfLaO, HfSiO, LaSiO, AlSiO, HfTaO, HfTiO, (Ba, Sr)TiO₃ (BST), Al₂O₃, Si₃N₄, oxynitrides (SiON), or other suitable materials. The high-κ layer can include a single layer or multiple layers, such as metal layer, liner layer, wetting layer, and adhesion layer. In other embodiments, the high-κ can include, e.g., Ti, Ag, Al, TiAlN, TaC, TaCN, TaSiN, Mn, Zr, TiN, TaN, Ru, Mo, Al, WN, Cu, W, or any suitable materials.

Replacement gate structure(s) 200 may be further formed by depositing a work function (WF) gate upon the high-κ layer. The WF gate can be comprised of a conductor or metal, such as, e.g., copper (Cu), cobalt (Co), aluminum (Al), platinum (Pt), gold (Au), tungsten (W), titanium (Ti), nitride (N) or any combination thereof. The metal can be deposited by a suitable deposition process, for example, chemical vapor deposition (CVD), plasma enhanced chemical vapor deposition (PECVD), physical vapor deposition (PVD), plating, thermal or e-beam evaporation, or sputtering. In general, the WF gate sets the threshold voltage (Vt) of the device. The high-κ layer may separate the WF gate from the nanolayer channel (i.e., active nanolayer 108). Other metals that may be desired to further fine tune the effective work function (eWF) and/or to achieve a desired resistance value associated with current flow through the gate in the direction parallel to the plane of the nanolayer channel.

The one or more replacement gate structures 200 may be further formed by depositing a conductive fill gate upon the WF gate. The conductive fill gate can be comprised of metals, such as but not limited to, e.g., tungsten, aluminum, ruthenium, rhodium, cobalt, copper, tantalum, titanium, carbon nanowire materials including graphene, or the like. The metal can be deposited by a suitable deposition process, for example, chemical vapor deposition (CVD), plasma enhanced chemical vapor deposition (PECVD), physical vapor deposition (PVD), plating, thermal or e-beam evaporation, or sputtering. After the replacement gate structure 200 formation, the top surface of the semiconductor IC device 100 may be planarized by a planarization technique such as a CMP, mechanical grinding process, or the like. After the planarization technique, respective top surfaces of the ILD 160, gate spacers 130, and replacement gate structure(s) 200, may be substantially horizontal and/or may be substantially coplanar.

FIG. 12 depicts cross-sectional views of the semiconductor IC device 100 after fabrication operations, in accordance with embodiments of the present disclosure. In the depicted fabrication stages, ILD 210 is formed, one or more frontside contact(s) 220 may be formed, and a frontside back end of line (BEOL) network (not shown) may be formed.

The ILD 210 may be formed upon respective top surfaces of replacement gate structure 200 and ILD 192. The ILD 210 may be formed by depositing a dielectric material, such as, for example, porous silicates, carbon doped oxides, silicon dioxides, silicon nitrides, silicon oxynitrides, or other dielectric materials. Any appropriate deposition technique for forming the ILD 210 can be utilized. The ILD 210 can be formed using, for example, CVD, PECVD, ALD, flowable CVD, spin-on dielectrics, or PVD.

The frontside contact(s) 220 may be formed by patterning respective frontside contact openings within the ILD 210, ILD 192, ILD 160, or the like, from the frontside (i.e., from above the semiconductor IC device 100, as depicted, downward to respective structures thereof). The frontside contact(s) 220 may be in direct or indirect physical and electrical contact of one or more regions of the semiconductor IC device 100. For example, a first frontside contact 220 may be in direct contact with top S/D region 190. Similarly, a second frontside contact 220 may be in direct contact with bottom S/D region 150. Similarly, a third frontside contact 220 (not shown) may be in direct contact with a replacement gate structure 200.

The frontside contact(s) 220 may be formed by initially forming frontside contact opening(s). The frontside contact opening(s) may be formed by the same or shared lithography and etch process(es), or sequential lithography and etch processes. In such process(es), a mask may be applied and patterned. An opening in the patterned mask may expose the portion of the underlying ILD 210 to be removed while other protected portions of semiconductor IC device 100 thereunder may be protected and retained. In such process(es), the etching processes can have etching parameters that can be tuned, such as etchants used, etching temperature, etching solution concentration, etching pressure, source power, RF bias voltage, RF bias power, etchant flow rate, to promote desired material removal and desired material retention.

The frontside contact(s) 220 may be further formed by depositing conductive material such as metal into the respective frontside contact opening(s). In an example, frontside contact(s) 220 may be formed by depositing a liner, such as Ni, NiPt or Ti, etc. into the contact opening(s), depositing a metal adhesion liner, such as TiN, TaN, etc. upon the liner, and by depositing a conductive metal fill, such as Al, Ru, W, Co, Cu, etc. upon the metal adhesion liner. Subsequently, a planarization process, such as a CMP process or a mechanical grinding process, may remove excess portions of the frontside contact 220 material(s). Subsequently, the respective top surfaces of frontside contact(s) 220 and ILD 210 may be coplanar.

In the semiconductor IC device fabrication industry, there are three sections referred to in a build: front-end-of-line (FEOL), back-end-of-line (BEOL), and the section that connects those two together, the middle-of-line (MOL). The FEOL is made up of the semiconductor devices, e.g., transistors, the BEOL is made up of interconnects and wiring, and the MOL is an interconnect between the FEOL and BEOL that includes material to prevent the diffusion of BEOL metals to FEOL devices. In the present example, the frontside contacts 220 may be illustrative MOL interconnect contacts.

BEOL is the second portion of IC fabrication where the individual devices (e.g., transistors, capacitors, resistors, etc.) become interconnected with wiring on the wafer, e.g., the metallization layer or layers. BEOL includes contacts, insulating layers (dielectrics), metal levels, and bonding sites for chip-to-package connections. In the BEOL, part of the fabrication stage contacts (pads), interconnect wires, vias and dielectric structures are formed. For modern IC processes, more than metal layers may be added in the BEOL.

A frontside BEOL network (not shown) may be formed over the ILD 210 and upon the frontside contacts 220. The frontside BEOL network may be indirectly electrically and/or physically connected to the S/D regions 150, one or more top S/D regions 190, and/or one or more replacement gate structures 200 by a one or more frontside contacts 220. The frontside BEOL network may be located directly on the frontside surface of the MOL structure (e.g., ILD 210, frontside contacts 220, etc.). The frontside BEOL network can include one or more interconnect dielectric material layers (including one of the dielectric materials mentioned above for the frontside ILD 160) and contains frontside metal wires (the metal wires can be composed of any electrically conductive metal or electrically conductive metal alloy) embedded therein. In some embodiments, the frontside metal wires within the frontside BEOL network are composed of Cu. The frontside BEOL network can include “x” numbers of frontside metal levels, wherein “x” is an integer starting from 1. The frontside BEOL network may further contain conductive pads that are connected to one or more of the metal wires and may be used to connect the semiconductor IC device to an external and/or higher-level structure, such as a chip carrier, motherboard, or the like.

For clarity, semiconductor IC device 100 may be an integrated circuit (IC) chip. IC chips can be distributed by the fabricator in raw wafer form (that is, as a single wafer that has multiple unpackaged chips), as a bare die, or in a packaged form. In the latter case, the IC chip may mount in a single chip package (such as a plastic carrier, with leads that are affixed to a motherboard or other higher-level carrier) or in a multichip package (such as a ceramic carrier that has either or both of surface interconnections and buried interconnections). In any case, the IC chip may be integrated with other chips, discrete circuit elements, and/or other signal processing devices as part of either (a) an intermediate product, such as a motherboard, or (b) an end product. The end product can be any product that includes the IC chip, ranging from toys and other low-end applications to advanced computer products having a display, a keyboard or other input device, and a central processor.

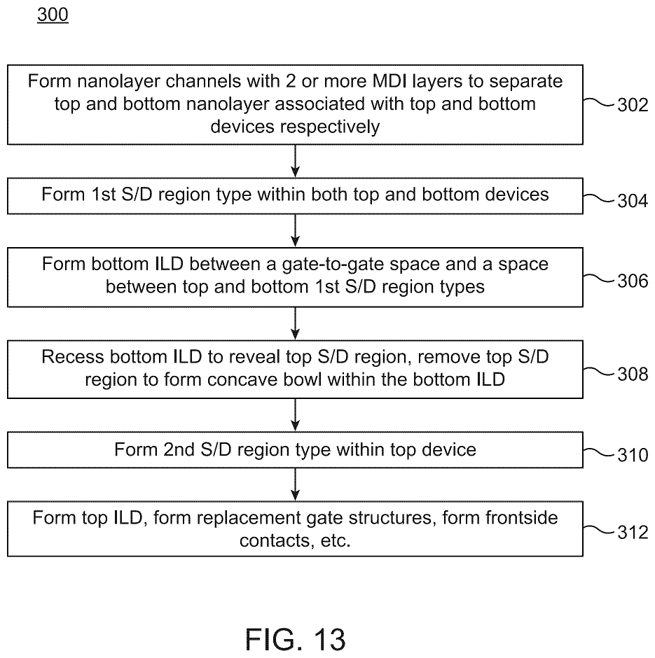

FIG. 13 depicts a flow diagram illustrating method 300 to fabricate a semiconductor IC device, such as semiconductor IC device 100. The depicted fabrication operations of method 300 are illustrated and described above with reference to one or more of FIG. 3 through FIG. 12 of the drawings, which describe the fabrication of semiconductor IC device 100, though the fabrication operations described in method 300 may be used to fabricate other types of semiconductor IC devices. The method 300 depicted herein is illustrative. There can be many variations to the diagram or operations described therein without departing from the spirit of the embodiments. For instance, the operations can be performed in a differing order, or operations can be added, deleted, or modified.

At block 302, method 300 may begin with forming nanolayer channels with two or more MDI layers that separate bottom nanolayer channels associated with a bottom device from top nanolayer channels associated with a top device. For example, a first series of alternating active nanolayers 108 and sacrificial nanolayers 106 may be formed upon a substrate, multiple MDI layers 132 may be formed over the first series of alternating active nanolayers 108 and sacrificial nanolayers 106, and a second series of alternating active nanolayers 108 and sacrificial nanolayers 106 may be formed over the multiple MDI layers 132.

At block 304, method 300 may continue with forming respective first S/D type regions within both the top device and the bottom device. For example, a bottom S/D region 150.1 is formed associated with the active nanolayers 108 that are below the multiple MDI layers 132 and a top S/D region 150.2 is formed associated with the active nanolayers 108 that are above the multiple MDI layers 132.

At block 306, method 300 may continue with forming a bottom ILD within a gate-to-gate space and between the first S/D type regions of both the top device and the bottom device. For example, ILD 160 is formed between the sacrificial gate structures 120, gate spacers 130, or the like, and in gap 152 between the top S/D region 150.2 and the bottom S/D region 150.1.

At block 308, method 300 may continue with partially recessing the bottom ILD to reveal of at least a portion of the first S/D type region of the top device. Further at block 308, the exposed first S/D type region of the top device is removed to form a concave bowl within the bottom ILD. For example, the ILD 160 is recessed so that a top surface of the ILD is inset between a top and bottom surface of top S/D region 150.2, thereby exposing the top S/D region 150.2. Subsequently, the exposed top S/D region 150.2 may be removed, thereby forming the concave bowl 182 within the ILD 160 and thereby exposing the previously associated active nanolayers 108 that are above the multiple MDI layers 132.

At block 310, method 300 may continue with forming a second S/D type region within the top device. For example, the top S/D region 190 is formed within the concave bowl 182 associated with the exposed active nanolayers 108 that are above the multiple MDI layers 132. The top S/D region 190 may be formed to overgrow or otherwise spill over the concave bowl 182 and, therefore, an extension or protrusion region of the top S/D region 190 may exist outside of the concave bowl 182 and be located over the top surface of the ILD 160.

At block 312, method 300 may continue with forming a top ILD, with forming replacement gate structures, with forming frontside contacts, and the like. For example, ILD 192 may be formed upon the ILD 160 and around the top S/D region 190. For example, sacrificial gate structures 120 may be removed, the active nanolayers 108 may be released, and a replacement gate structure 200 may be formed. For example, frontside contacts 220 may be formed in contact with a respective bottom S/D region 150 and/or a respective top S/D region 190.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A stacked transistor comprising:
a top source/drain (S/D) region comprising a lower portion and an upper portion;
a bottom S/D region below the top S/D region;
a bottom interlayer dielectric (ILD) in contact with the bottom S/D region and in contact with the lower portion of the top S/D region; and
a top ILD in contact with the upper portion of the top S/D region.

2. The stacked transistor of claim 1, wherein a largest horizontal dimension of the upper portion of the top S/D region is greater that a largest horizontal dimension of the lower portion of the top S/D region.

3. The stacked transistor of claim 1, wherein a horizontal dimension of the top S/D is greatest at an interface between the bottom ILD and the top ILD.

4. The stacked transistor of claim 3, wherein the interface between the bottom ILD and the top ILD is horizontally planar.

5. The stacked transistor of claim 3, wherein the interface between the bottom ILD and the top ILD is non-planar.

6. The stacked transistor of claim 1, further comprising:
a multi-layered middle dielectric isolation (MDI) structure comprising a bottom MDI layer and a top MDI layer.

7. The stacked transistor of claim 6, wherein the bottom MDI layer is directly connected to the bottom ILD and wherein the top MDI layer is directly connected to the bottom ILD.

8. The stacked transistor of claim 6, wherein the multi-layered MDI structure is between top channels that are directly connected to the top S/D region and bottom channels that are directly connected to the bottom S/D region.

9. The stacked transistor of claim 8, wherein the top channels, the bottom channels, the top MDI layer, and the bottom MDI layer have a substantially same vertical thickness.

10. The stacked transistor of claim 8, further comprising:
a shared gate structure around each of the top channels, around each of the bottom channels, around the top MDI layer, and around the bottom MDI layer.

11. A stacked transistor comprising:
a top source/drain (S/D) region comprising a lower portion and an upper portion;
a bottom interlayer dielectric (ILD) in contact with the lower portion of the top S/D region; and
a top ILD in contact with the upper portion of the top S/D region.

12. The stacked transistor of claim 11, wherein a largest horizontal dimension of the upper portion of the top S/D region is greater that a largest horizontal dimension of the lower portion of the top S/D region.

13. The stacked transistor of claim 11, wherein a horizontal dimension of the top S/D is greatest at an interface between the bottom ILD and the top ILD.

14. The stacked transistor of claim 13, wherein the interface between the bottom ILD and the top ILD is horizontally planar.

15. The stacked transistor of claim 13, wherein the interface between the bottom ILD and the top ILD is non-planar.

16. The stacked transistor of claim 11, further comprising:
a multi-layered middle dielectric isolation (MDI) structure comprising a bottom MDI layer and a top MDI layer.

17. The stacked transistor of claim 16, wherein the bottom MDI layer is directly connected to the bottom ILD and wherein the top MDI layer is directly connected to the bottom ILD.

18. The stacked transistor of claim 16, wherein the multi-layered MDI structure is below top channels that are directly connected to the top S/D region.

19. The stacked transistor of claim 18, wherein the top channels, the top MDI layer, and the bottom MDI layer have a substantially same vertical thickness.

20. A stacked transistor comprising:
a bottom source/drain (S/D) region;
a top S/D region that is offset from the bottom S/D region, the top S/D region comprising a lower portion that is inset relative to an upper portion; and
an interlayer dielectric (ILD);
wherein the upper portion of the top S/D region comprises a bottom surface that is substantially coplanar with a top surface of the ILD.
